(19) United States
(12) Patent Application Publication
(10) Pub. No.: US 2015/0144941 A1
(43) Pub. Date: May 28, 2015

(54) DISPLAY SUBSTRATE COMPRISING PIXEL TFT AND DRIVING TFT AND PREPARATION METHOD THEREOF

(71) Applicant: SAMSUNG DISPLAY CO., LTD., Yongin-si (KR)

(72) Inventors: Masataka KANO, Hwaseong-si (KR); Sang-Ho PARK, Suwon-si (KR); So-Young KOO, Yongin-si (KR); Myoung-Hwa KIM, Seoul (KR); Yeon-Hong KIM, Hwaseong-si (KR); Jung-Hun NOH, Yongin-si (KR); Jun-Hyung LIM, Seoul (KR); Sang-Hee JANG, Bucheon-si (KR)

(21) Appl. No.: 14/512,244

(22) Filed: Oct. 10, 2014

(30) Foreign Application Priority Data
Nov. 27, 2013 (KR) 10-2013-0145130

(51) Int. Cl. H01L 27/12

(52) U.S. Cl. CPC H01L 27/1251; H01L 27/1225; H01L 27/1262; H01L 27/127
USPC 257/43; 438/104

(57) ABSTRACT

Disclosed is a display substrate including a driving unit on a substrate comprising a first thin film transistor and a display unit on the substrate being adjacent to the driving unit and comprising a second thin film transistor.

### CROSS-REFERENCE TO RELATED APPLICATION

This application claims priority to and the benefit of Korean Patent Application No. 10-2013-0145130, filed on Nov. 27, 2013, with the Korean Intellectual Property Office, the disclosure of which is incorporated herein in its entirety by reference.

### BACKGROUND

1. Field

Embodiments of the present invention relate to a display substrate in which a pixel thin film transistor and a driving thin film transistor, which are different from each other in configurations, are provided on one substrate, and to a manufacturing method thereof.

2. Description of the Related Art

A display device is provided with a display substrate having a plurality of pixels. In other words, the display devices such as liquid crystal display (LCD), organic light emitting diode display (OLED display), and electrophoretic display include a plurality of pixels on a display substrate, and each pixel includes a pair of electrodes and an optical active layer activated by voltage or current applied to the pair of electrodes. For example, the liquid crystal display (LCD) includes a liquid crystal layer as the optical active layer, and the organic light emitting diode display (OLED display) includes an organic light emitting layer as the optical active layer.

Such display devices include a switching element connected to a pixel electrode of the pair of electrodes to switch electric signals, and the optical active layer is activated by the electric signals to display images. In this case, the switching element receives data signals from a data line and transmits them to the pixel electrode according to a scanning signal from a gate line. The switching element mainly includes a thin film transistor (TFT).

The pixel electrode, the switching element, the gate line, and the data line are formed on at least one display substrate. A pixel area is defined by the gate line, the data line, a black matrix, or a pixel defining layer, and a portion provided with a plurality of pixel areas is called a “display unit.”

The display device also includes a gate driver applying scanning signals to the gate line and a data driver applying data signals to the data line. The gate driver and the data driver are operated according to control signals transmitted from a signal controller. The gate driver and the data driver are called a “driving unit,” and the driving unit is formed on a separate substrate, e.g., flexible substrate, and is electrically connected to a display substrate by a separate connection member. However, in the case where the driving unit is formed on a separate substrate, and then is connected to a display substrate, the total volume of the display device increases. For this reason, there is an attempt to form the driving unit, the pixel electrode, and the switching element together on the display substrate.

The driving unit includes a plurality of active elements made of TFTs, and the TFT of the driving unit and the TFT acting as the switching element of the display unit may not be consistent with each other in required characteristics. However, in the case where the TFT of the driving unit and the TFT of the display unit are configured in different ways so as to meet requirements of the different characteristics, a manufacturing process may be complicated. Therefore, the TFT of the driving unit and the TFT of the display unit are often configured in the same way.

### SUMMARY

Aspects of embodiments of the present invention are directed to a display substrate in which a thin film transistor (TFT) of a driving unit and a TFT of a display unit, which are different from each other in configurations, are disposed on one substrate.

Further, aspects of embodiments of the present invention are directed to a method of manufacturing a display substrate in which a TFT of a driving unit and a TFT of a display unit, which are different from each other in configurations, are formed on one substrate.

According to an embodiment of the present invention, a display substrate includes a substrate; a driving unit on the substrate, the driving unit comprising a first thin film transistor (TFT); and a display unit on the substrate, the display unit being adjacent to the driving unit and comprising a second TFT. The first TFT may include a first gate electrode on the substrate; a first gate insulating layer on the first gate electrode; a first semiconductor layer on the first gate insulating layer, overlapping at least a part of the first gate electrode; a first insulating layer on at least a part of the first semiconductor layer; and a first source electrode and a first drain electrode partly on the first semiconductor layer and partly on the first insulating layer, the first source and drain electrodes being spaced apart from each other. The second TFT may include a second gate electrode on the substrate; a second gate insulating layer on the second gate electrode; a second semiconductor layer on the second gate insulating layer, overlapping at least a part of the second gate electrode; a second source electrode and a second drain electrode on the second semiconductor layer, the second source and drain electrodes being spaced apart from each other; and a second insulating layer on the second source electrode and the second drain electrode.

According to another embodiment of the present invention, a display substrate includes: a driving unit on a substrate, including a first thin film transistor (TFT); and a display unit on the substrate, being adjacent to the driving unit and including a second TFT. Herein, the first TFT includes: a first gate electrode on the substrate; a first gate insulating layer on the first gate electrode; a first semiconductor layer on the first gate insulating layer, overlapping at least a portion of the first gate electrode; a first insulating layer on at least a portion of the first semiconductor layer; and a first source electrode and a first drain electrode spaced apart from each other on the first semiconductor layer and the first insulating layer. Further, the second TFT includes: a second gate electrode on the substrate; a second gate insulating layer on the second gate electrode; a second semiconductor layer on the second gate insulating layer, overlapping at least a portion of the second gate electrode; a second source electrode and a second drain electrode spaced apart from each other on the second semiconductor layer; and a second insulating layer on the second source electrode and the second drain electrode.

The display substrate further includes a pixel electrode on the second insulating layer, being connected to the second drain electrode through a contact hole of the second insulating layer.

The pixel electrode is made of the same material as the first source electrode and the first drain electrode.

The pixel electrode, the first source electrode, and the first drain electrode includes at least one selected from the group consisting of metals and transparent conducting oxides (TCOs).

The first and second semiconductor layers are an oxide semiconductor layer.

The oxide semiconductor layer includes at least one selected from the group consisting of zinc (Zn), gallium (Ga), indium (In), and tin (Sn).

The oxide semiconductor layer includes indium (In), gallium (Ga), zinc (Zn), and oxygen (O).

The display substrate further includes an etch stopper on the first semiconductor layer.

The first insulating layer is made of the same material as the second insulating layer.

The driving unit includes at least one of a data driver and a gate driver.

According to another embodiment, a method of manufacturing a display substrate includes forming a first gate electrode and a second gate electrode on a substrate; forming a gate insulating layer on the first gate electrode and the second gate electrode; forming a first semiconductor layer and a second semiconductor layer respectively overlapping at least a part of the first gate electrode and a part of the second gate electrode on the gate insulating layer; forming a first insulating layer on at least a part of the first semiconductor layer; forming a first source electrode and a first drain electrode spaced apart from each other on the first semiconductor layer and the first insulating layer; forming a second source electrode and a second drain electrode spaced apart from each other on the second semiconductor layer; and forming a second insulating layer on the second source electrode and the second drain electrode, having a contact hole configured to expose a part of the second drain electrode.

According to another embodiment of the present invention, a method of manufacturing a display substrate includes: forming a first gate electrode and a second gate electrode on a substrate; forming a gate insulating layer configured to cover the first gate electrode and the second gate electrode; forming a first semiconductor layer and a second semiconductor layer respectively overlapping at least a part of the first gate electrode and a part of the second gate electrode; forming a first insulating layer on at least a part of the first semiconductor layer; forming a first source electrode and a first drain electrode spaced apart from each other on the first semiconductor layer and the first insulating layer; forming a second source electrode and a second drain electrode spaced apart from each other on the second semiconductor layer; and forming a second insulating layer on the second source electrode and the second drain electrode, having a contact hole configured to expose a part of the second drain electrode.

The method further includes forming a pixel electrode connected to the second drain electrode through the contact hole of the second insulating layer.

The forming of the pixel electrode is performed simultaneously with the forming of the first source electrode and the first drain electrode.

The forming of the pixel electrode and the forming of the first source electrode and the first drain electrode include coating a second conductive material on the first semiconductor layer, and the first and second insulating layers, and etching the second conductive material selectively.

The forming of the first and second semiconductor layers and the forming of the second source electrode and the second drain electrode are performed by the same mask.

The forming of the first and second semiconductor layers and the forming of the second source electrode and the second drain electrode include coating a semiconductor material and a first conductive material sequentially on the gate insulating layer, and etching the semiconductor material and the first conductive material selectively.

The semiconductor material includes an oxide semiconductor material.

The forming of the first insulating layer is performed simultaneously with the forming of the second insulating layer.

According to embodiments of the present invention, the TFTs of the driving unit and the display unit, which have different configurations, may be easily fabricated on one substrate, and thus the number of pattern masks used to fabricate the TFTs of the driving unit and the display unit may be reduced.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the present invention will be more clearly understood from the following detailed description taken in conjunction with the accompanying drawings, in which:

FIG. 1 is a plan view showing a display substrate including a driving unit and a display unit formed together on one substrate according to an embodiment of the present invention;

FIG. 2 is a plan view showing a driving thin film transistor provided in a driving unit and a pixel thin film transistor provided in a display unit according to an embodiment of the present invention;

FIG. 3 is a cross-sectional view of first and second thin film transistors according to an embodiment of the present invention;

FIG. 4 is a cross-sectional view of first and second thin film transistors according to another embodiment of the present invention;

FIGS. 5A to 5K are cross-sectional views illustrating a process of manufacturing a display substrate according to an embodiment of the present invention;

FIGS. 6A and 6B are graphs showing current density varying with gate voltage applied to an oxide semiconductor thin film transistor with a back channel etch (BCE) structure and an oxide semiconductor thin film transistor with an etch stopper (ES) structure;

FIGS. 7A and 7B are graphs showing current density before and after voltage stress is applied in an oxide semiconductor thin film transistor with a back channel etch (BCE) structure and an oxide semiconductor thin film transistor with an etch stopper (ES) structure; and

FIGS. 8A and 8B are graphs showing threshold voltage before and after voltage stress is applied in an oxide semiconductor thin film transistor with a back channel etch (BCE) structure and an oxide semiconductor thin film transistor with an etch stopper (ES) structure.

### DETAILED DESCRIPTION

Hereinafter, embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, certain elements or shapes may be simplified or exaggerated to better illustrate the present invention, and other elements present in an actual product may also be omitted. Thus, the drawings are intended to facilitate the understanding of the present invention. Like reference numerals refer to like elements throughout the specification.

In addition, when a layer or element is referred to as being “on” another layer or element, the layer or element may be directly on the other layer or element, or one or more intervening layers or elements may be interposed therebetween.

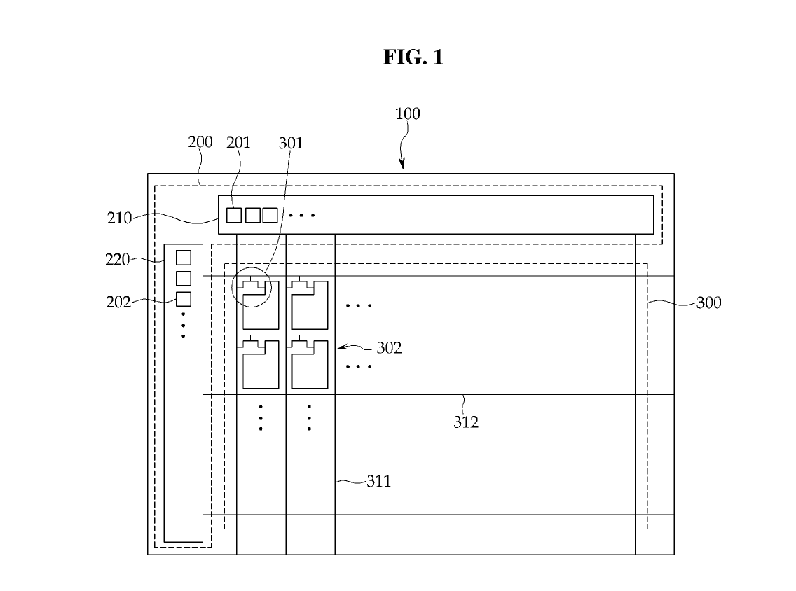

FIG. 1 illustrates a display substrate in which a driving unit 200 and a display unit 300 are formed together on one substrate 100.

The driving unit 200 includes a data driver 210 and a gate driver 220, and the data driver 210 and the gate driver 220 include a plurality of thin film transistors (TFTs) 201 and 202, respectively. Hereinafter in the present disclosure, the TFTs 201 and 202 disposed in the driving unit 210 may be called a “first TFT.”

The display unit 300 includes a pixel electrode 163 and a pixel TFT 301 provided in a plurality of pixel areas 302 defined by a data line 311 and a gate line 312 intersecting each other, a black matrix, or a pixel defining layer. Hereinafter in the present disclosure, the pixel TFT 301 may be called a “second TFT.”

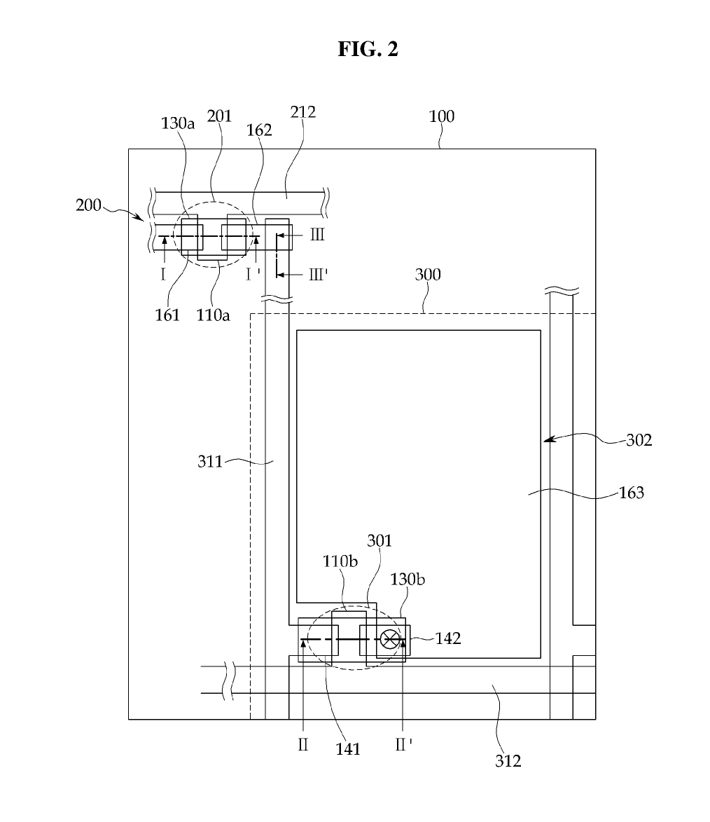

FIG. 2 illustrates a driving TFT disposed in the driving unit and a pixel TFT disposed in the display unit. A driving TFT of the data driver 210 is exemplified as the driving TFT (e.g., a first TFT 201) of FIG. 2. Although not illustrated, a driving TFT of the gate driver 220 may be configured in the same manner as the driving TFT (e.g., the first TFT 201) of the data driver 210.

The first TFT 201, which is a driving TFT, includes a first gate electrode 110a, a first semiconductor layer 130a, a first source electrode 161, and a first drain electrode 162 that are disposed on the substrate 100.

The second TFT 301, which is a pixel TFT, includes a second gate electrode 110b, a second semiconductor layer 130b, a second source electrode 141, and a second drain electrode 142 that are disposed on the substrate 100.

The first TFT 201 illustrated in FIG. 2 is connected to the data line 311 via the first drain electrode 162. Although not illustrated, another element may be interposed between the first drain electrode 162 and the data line 311.

The present invention is not limited to the embodiment depicted in FIG. 2. For example, the driving unit 200 may include a plurality of TFTs that are different from the first TFT 201 illustrated in FIG. 2. Some TFTs of the driving unit 200 may be connected to the data line 311 of the pixel TFT, and other TFTs of the driving unit 200 may not be connected to the data line 311 of the pixel TFT.

The data line 311 is connected to the second TFT 301 via the second source electrode 141.

FIG. 3 is cross-sectional views of the first TFT 201 and the second TFT 301, taken along lines I-I′ and II-II′ of FIG. 2, respectively.

Hereinafter, referring to FIGS. 2 and 3, the first TFT 201 and the second TFT 301 will be described in more detail.

In the example illustrated in FIGS. 2 and 3, gate lines 212 and 312, and gate electrodes 110a and 110b are disposed on the substrate 100 made of glass, plastic, or the like. In other words, the first gate line 212 and the first gate electrode 110a are disposed in the driving unit 200, and the second gate line 312 and the second gate electrode 110b are disposed in the display unit 300. FIG. 2 illustrates only the first gate line 212 and the first gate electrode 110a that are disposed in the data driver 210 of the driving unit 200, but the gate line and the gate electrode may be disposed in the gate driver 220 illustrated in FIG. 1.

The gate lines 212 and 312, and the gate electrodes 110a and 110b may be made of aluminum-based metal such as aluminum (Al) or aluminum alloy, silver-based metal such as silver (Ag) or silver alloy, copper-based metal such as copper (Cu) or copper alloy, molybdenum-based metal such as molybdenum (Mo) or molybdenum alloy, chromium (Cr), tantalum (Ta), titanium (Ti), or the like. The gate lines 212 and 312, and the gate electrodes 110a and 110b may have a multilayer structure in which two or more conductive layers having different physical or chemical properties are laminated.

A gate insulating layer 120 including silicon nitride (SiNx), silicon oxide (SiOx), or the like is disposed on the entire surface of the surface 100 provided with the gate lines 212 and 312, and the gate electrodes 110a and 110b. The gate insulating layer 120 may have a multilayer structure in which two or more insulating layers having different physical or chemical properties are included.

Hereinafter in the present disclosure, the gate insulating layer on the first gate electrode 110a may be called a “first gate insulating layer,” and the gate insulating layer on the second gate electrode 110b may be called a “second gate insulating layer.” In FIG. 3, the first and second gate insulating layers are a common gate insulating layer 120 formed by using the same material and process.

The semiconductor layers 130a and 130b are disposed on the gate insulating layer 120. The first semiconductor layer 130a of the first TFT 201 overlaps (e.g., in the horizontal direction as shown in FIG. 3) at least a part of the first gate electrode 110a, and the second semiconductor layer 130b of the second TFT 301 overlaps (e.g., in the horizontal direction as shown in FIG. 3) at least a part of the second gate electrode 110b.

The semiconductor layers 130a and 130b may be made of a semiconductor material such as amorphous silicon or polycrystalline silicon, or may be made of an oxide semiconductor material.

The first and second semiconductor layers 130a and 130b of FIG. 3 are an oxide semiconductor layer. The oxide semiconductor layer may include at least one selected from the group consisting of zinc (Zn), gallium (Ga), indium (In), and tin (Sn).

For example, the oxide semiconductor layer may be formed by using an oxide based on zinc (Zn), gallium (Ga), tin (Sn), or indium (In), or an oxide semiconductor material such as zinc oxide (ZnO), indium-gallium-zinc oxide (InGaZnO₄), Indium-zinc oxide (In—Zn—O), and zinc-tin oxide (Zn—Sn—O), which are complex oxides.

In some embodiments, the oxide semiconductor layer may include an IGZO-based oxide consisting of indium (In), gallium (Ga), zinc (Zn) and oxygen (O). In addition, the oxide semiconductor layer may include In—Sn—Zn—O-based metal oxide, In—Al—Zn—O-based metal oxide, Sn—Ga—Zn—O-based metal oxide, Al—Ga—Zn—O-based metal oxide, Sn—Al—Zn—O-based metal oxide, In—Zn—O-based metal oxide, Sn—Zn—O-based metal oxide, Al—Zn—O-based metal oxide, In—O-based metal oxide, Sn—O-based metal oxide, and Zn—O-based metal oxide.

Although not illustrated, an ohmic contact member may be disposed on the semiconductor layers 130a and 130b.

The second source electrode 141 and the second drain electrode 142, which are made of a first conductive material, are disposed on the second semiconductor layer 130b, and the data line 311 made of the first conductive material is disposed on the gate insulating layer 120. The second source electrode 141, the second drain electrode 142, and the data line 311 may be formed by using the same conductive material as the gate lines 212 and 312, and the gate electrodes 110a and 110b, or may be formed by using different conductive materials.

In some embodiments, the second source electrode 141, the second drain electrode 142, and the data line 311 may be made of a refractory metal such as molybdenum, chromium, tantalum and titanium, or their alloys, and may have a multilayer structure that includes a refractory metal layer and a low resistance conductive layer. The multilayer structure may include, for example, a double layer consisting of a chromium or molybdenum (its alloy) lower layer and an aluminum (its alloy) upper layer, and a triple layer consisting of a molybdenum (its alloy) lower layer, an aluminum (its alloy) intermediate layer, and a molybdenum (its alloy) upper layer.

The second source electrode 141, the second drain electrode 142, and the data line 311 may be formed by using many different conductive materials besides the above-mentioned materials. For instance, the second source electrode 141, the second drain electrode 142, and the data line 311 may include copper (Cu). In other words, the second source electrode 141, the second drain electrode 142, and the data line 311 may be made of copper or copper alloys, and may have a multilayer structure containing copper. The multilayer structure may include, for example, a double layer in which a layer containing at least one of gallium zinc oxide (GZO), indium tin oxide (ITO), indium zinc oxide (IZO), aluminum zinc oxide (AZO), and titanium (Ti) is laminated on an upper part or lower part of copper, or a triple layer in which a layer containing at least one of gallium zinc oxide (GZO), indium tin oxide (ITO), indium zinc oxide (IZO), aluminum zinc oxide (AZO), and titanium (Ti) is laminated respectively on an upper part and lower part of copper.

The data line 311 may include a terminal part configured for connection to a different layer or an external driver circuit, and for example the terminal part may be configured to connect the data line 311 to the first TFT 201 of the driving unit. The data line 311 transmits data signals, and mostly extends in a longitudinal direction to intersect the second gate line 312 of the display unit 300. As illustrated in FIGS. 1 and 2, the pixel area 302 may be defined by the data line 311 and the second gate line 312.

The second source electrode 141 may be extended from the data line 311 to be disposed on the second semiconductor layer 130b. The second drain electrode 142 is disposed on the second semiconductor layer 130b such that the second drain electrode 142 is spaced apart from the second source electrode 141.

The second TFT 301 may include the second gate electrode 110b, the second source electrode 141, the second drain electrode 142, and the second semiconductor layer 130b. A channel of the second TFT 301 may be formed on the second semiconductor layer 130b between the second source electrode 141 and the second drain electrode 142. As shown in the second TFT 301 of FIG. 3, a structure that exposes a channel of a semiconductor layer between a source electrode and a drain electrode is referred to as a “back channel etch (BCE).” The BCE structure will be described below with respect to a TFT manufacturing process.

The first source electrode 161 and the first drain electrode 162 of the first TFT 201 may be made of different materials from the data line 311 on the first semiconductor layer 130a, while the second source electrode 141 and the second drain electrode 142 of the second TFT 301 are made of the same material as the data line 311.

An insulating layer may be disposed on an exposed portion of the second source electrode 141, the second drain electrode 142, and the second semiconductor layer 130b, and on the first semiconductor layer 130a. The insulating layer may also be disposed on the gate insulating layer 120 and on the pixel area where the pixel electrode may be formed.

FIG. 3 illustrates a passivation layer disposed to act as the insulating layer.

A first passivation layer 150a may be disposed on the first semiconductor layer 130a, and the first passivation layer 150a may be the first insulating layer. The first passivation layer 150a may be disposed on an area corresponding to a channel area of the first semiconductor layer 130a.

The first source electrode 161 and the first drain electrode 162 are spaced apart from each other on a part of the first passivation layer 150a formed on the first semiconductor layer 130a, and on the first semiconductor layer 130a separated from each other by the first passivation layer 150a. As shown in the first TFT 201 of FIG. 3, a structure that has a source electrode and a drain electrode arranged on a protective layer or passivation layer and a semiconductor layer is referred to as an “etch stopper (ES).” In the case of the ES structure, the protective layer or passivation layer is disposed on the semiconductor layer before the source electrode and the drain electrode are disposed, and the protective layer or passivation layer (e.g., the first passivation layer 150a in FIG. 3) acts as an etch stopper.

A second passivation layer 150b is disposed on the second source electrode 141, the second drain electrode 142, and the second semiconductor layer 130b. The second passivation layer 150b may be the second insulating layer.

The first and second passivation layers 150a and 150b may be made of an inorganic insulator such as silicon nitride (SiNx) or silicon oxide (SiOx), or may be made of an organic insulation material. Further, the first and second passivation layers 150a and 150b may have a multilayer structure including inorganic and organic layers in order to promote excellence of insulating properties and protect the semiconductor layers 130a and 130b. The passivation layers 150a and 150b may have a thickness of about 5000 Å or more, e.g., a thickness of about 6000 Å to about 8000 Å.

The pixel electrode 163 is disposed on the second passivation layer 150b that is an insulating layer of the pixel area 302. The second passivation layer 150b has a contact hole configured to expose a part of the second drain electrode 142, so that the pixel electrode 163 and the second drain electrode 142 may be electrically connected to each other through the contact hole.

In the embodiment of FIGS. 2 and 3, the first source electrode 161 and the first drain electrode 162 of the first TFT 201 may be made of the same material as the pixel electrode 163. The first source electrode 161 and the first drain electrode 162 may be formed in conjunction with the pixel electrode 163. For example, the first source electrode 161, the first drain electrode 162, and the pixel electrode 163 may be formed in the same process.

The first source electrode 161, the first drain electrode 162, and the pixel electrode 163 may be made of a second conductive material, and the second conductive material may be transparent. A transparent conducting oxide (TCO) may be used as such a transparent material. The TCO may include, for example, indium tin oxide (ITO), indium zinc oxide (IZO), or aluminum doped zinc oxide (AZO), which is polycrystalline, monocrystalline, or amorphous.

The TCO has higher resistance than a metal, and thus the first source electrode 161 and the first drain electrode 162 of the first TFT 201, which are made of the TCO, may not be efficient in signal transmission. In order to minimize the inefficiency in signal transmission, the data line 311 extends to the first drain electrode 162 of the first TFT 201 so that the data line 311 and the first drain electrode 162 may partially overlap each other as illustrated in FIG. 2. In this case, the first drain electrode 162 may transmit signals easily to the data line 311.

In the case where the pixel electrode 163 does not need to be transparent, the pixel electrode 163, the first source electrode 161, and the first drain electrode 162 may be formed by using a metallic conductor.

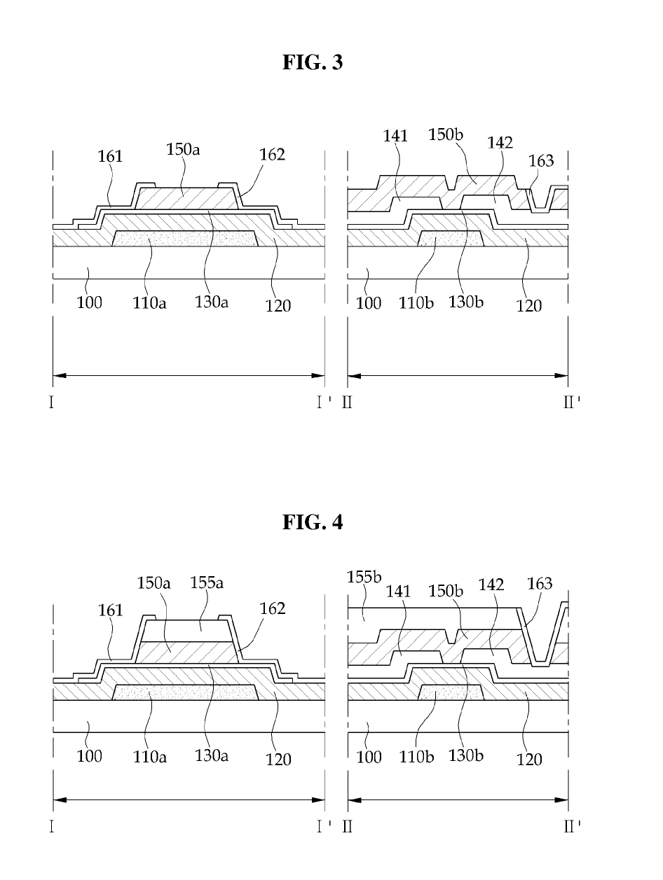

FIG. 4 is a cross-sectional view of first and second TFTs 201 and 301 according to another embodiment of the present invention.

The first and second TFTs 201 and 301 illustrated in FIG. 4 include a passivation layer and a planarization layer as an insulating layer. In the example of FIG. 4, a first planarization layer 155a is disposed on a first passivation layer 150a of the first TFT 201, and a second planarization layer 155b is disposed on a second passivation layer 150b of the second TFT 301. Herein, the first passivation layer 150a and the first planarization layer 155a are included in a first insulating layer, and the second passivation layer 150b and the second planarization layer 155b are included in a second insulating layer.

Further layers having insulating properties may be interposed between the passivation layers 150a and 150b and the planarization layers 155a and 155b.

In the first TFT 201 of FIG. 4, a first source electrode 161 and a first drain electrode 162 are disposed to be spaced apart from each other on the first passivation layer 150a, the first planarization layer 155a, and a first semiconductor layer 130a.

Further, a pixel electrode 163 is disposed on the second passivation layer 150b and the second planarization layer 155b of a pixel area 302. The second passivation layer 150b and the second planarization layer 155b are penetrated by a contact hole configured to connect a second drain electrode 142 and the pixel electrode 163. The pixel electrode 163 and the second drain electrode 142 are connected to each other through the contact hole.

The planarization layers 155a and 155b may be made of the same material as the passivation layers 150a and 150b. In some embodiments, the planarization layers 155a and 155b may be made of an inorganic insulator such as silicon nitride (SiNx) or silicon oxide (SiOx), or may be made of an organic insulation material. Further, the planarization layers 155a and 155b may have a multilayer structure including inorganic and organic layers.

In some embodiments, the present invention provides a method of manufacturing a display substrate in which first and second TFTs, which are different from each other in configuration, are formed on one substrate.

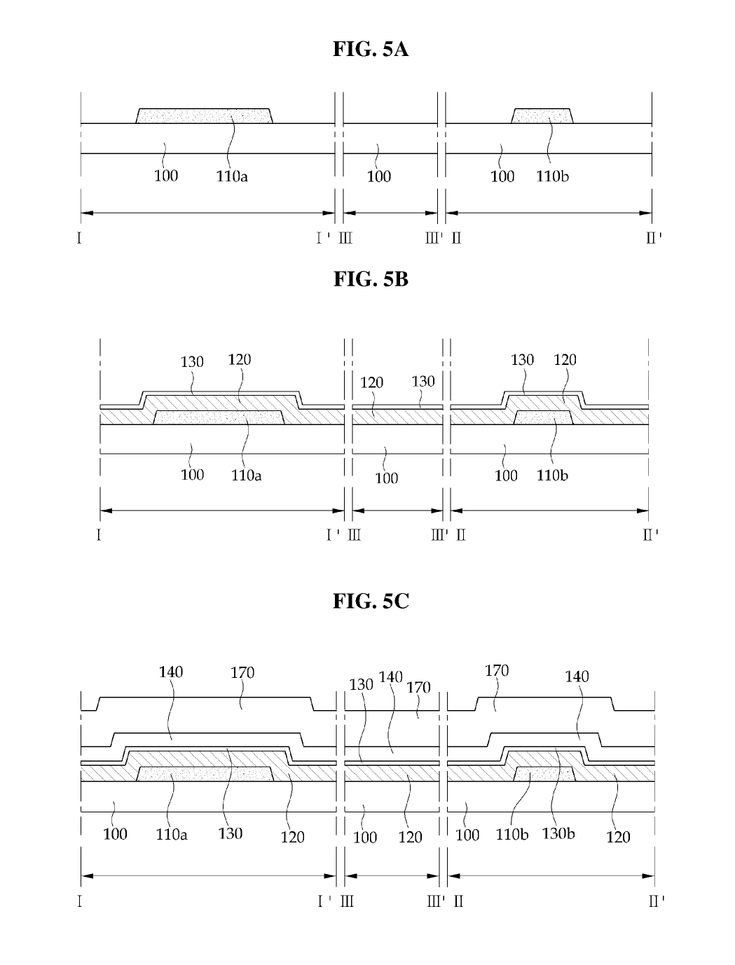

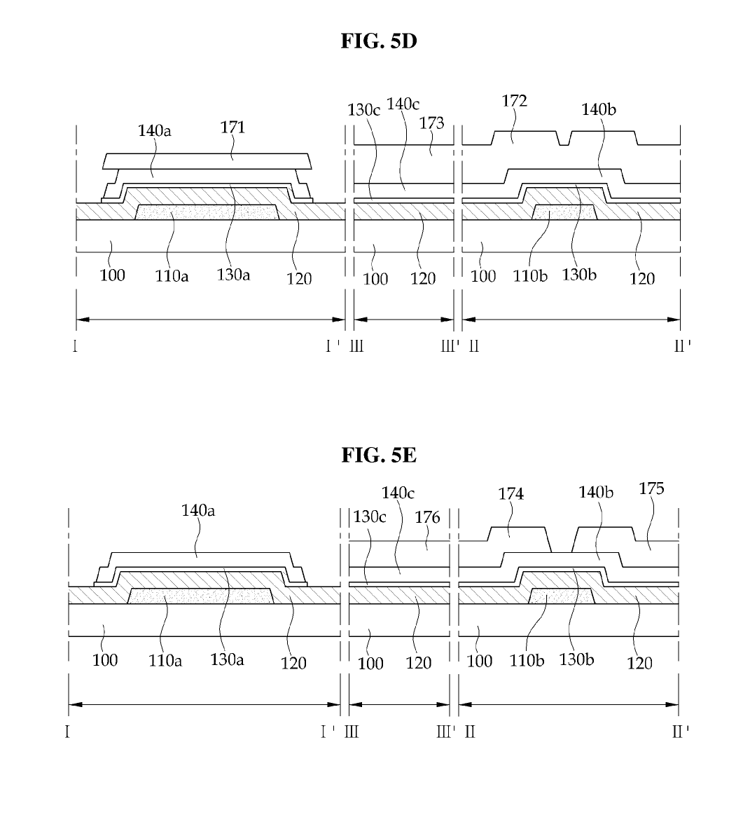

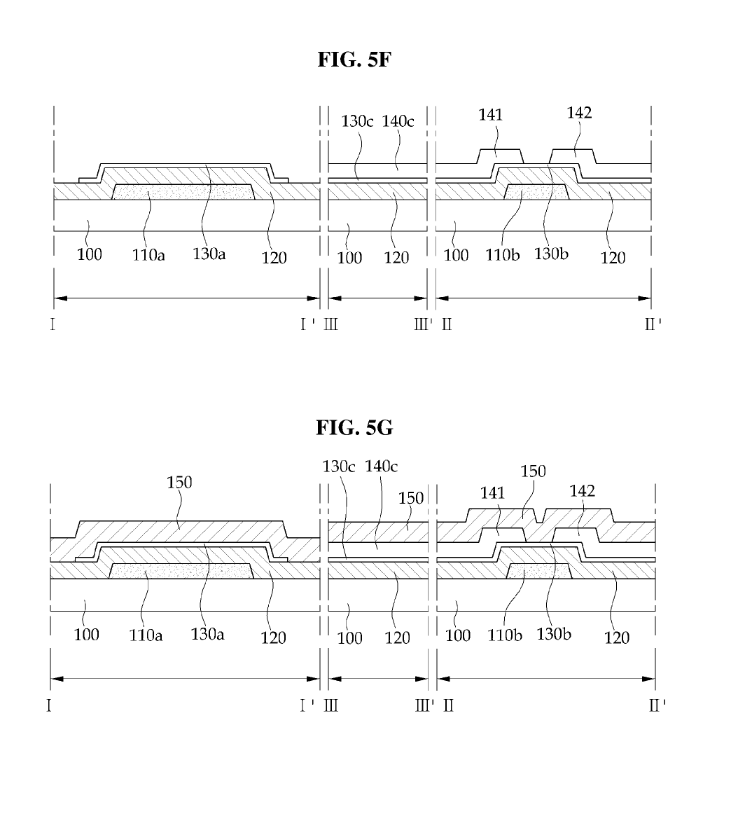

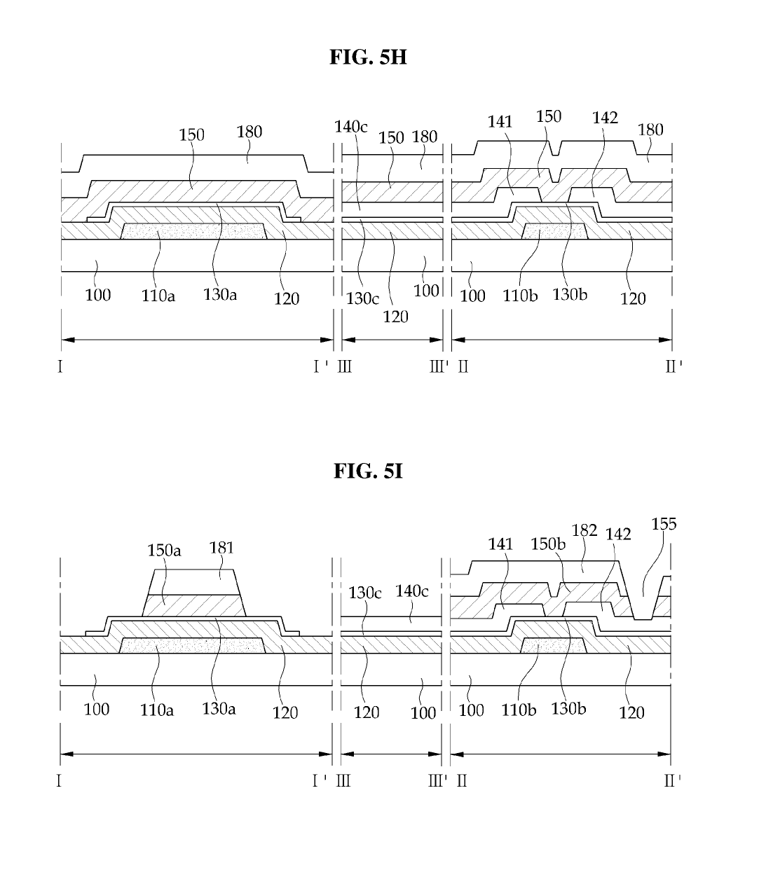

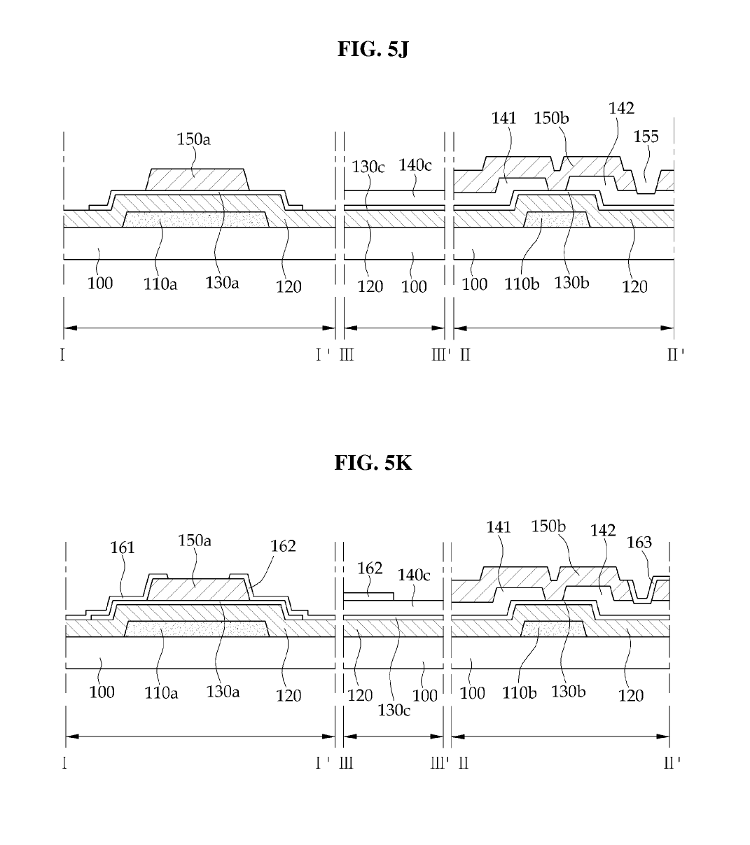

Hereinafter, a process for manufacturing a display substrate according to an embodiment of the present invention will be described with reference to FIGS. 5A to 5K.

FIGS. 5A to 5K illustrate a manufacturing process of first and second TFTs 201 and 301, and also a manufacturing process of a data line 311 connected to the first TFT 201.

The cross-sectional views of FIGS. 5A to 5K are taken along lines I-I′, II-II′, and III-III′ of FIG. 2, respectively. Herein, the cross-sectional view taken along line I-I′ of FIG. 2 corresponds to the first TFT 201, the cross-sectional view taken along line II-II′ of FIG. 2 corresponds to the second TFT 301, and the cross-sectional view taken along line III-III′ of FIG. 2 corresponds to the data line 311.

First, gate lines 212 and 312 and gate electrodes 110a and 110b are formed on a substrate 100 made of glass, plastic, or the like (see FIG. 5A). In the example of FIG. 5A, the first gate line 212 and the first gate electrode 110a are formed in a driving unit, and the second gate line 312 and the second gate electrode 110b are formed in a display unit. The gate lines 212 and 312 and the gate electrodes 110a and 110b have been previously discussed regarding their forming methods and materials, and hence further description thereof will be omitted for the sake of brevity.

A first pattern mask M1 is used in a process for forming the gate lines 212 and 312 and the gate electrodes 110a and 110b.

A gate insulating layer 120 including silicon nitride (SiNx), silicon oxide (SiOx), or the like is formed on the entire surface of the surface 100 provided with the gate lines 212 and 312, and the gate electrodes 110a and 110b. The gate insulating layer 120 may have a multilayer structure in which two or more insulating layers having different physical or chemical properties are included.

The gate insulating layer on the first gate electrode 110a is called a “first gate insulating layer,” and the gate insulating layer on the second gate electrode 110b is called a “second gate insulating layer.” In FIGS. 5A to 5K, the first and second gate insulating layers may be formed as one gate insulating layer 120 together by using the same material and process.

A semiconductor material 130 is disposed over the entire surface of the gate insulating layer 120 (see FIG. 5B).

The semiconductor material 130 may include a silicon-based semiconductor material such as amorphous silicon or polycrystalline silicon, or an oxide semiconductor material.

In the case where the semiconductor material 130 is amorphous silicon, the semiconductor material 130 is irradiated with laser so that amorphous silicon may be crystallized.

In FIG. 5B, an oxide semiconductor material is used as the semiconductor material 130. The oxide semiconductor material may include at least one selected from the group consisting of zinc (Zn), gallium (Ga), indium (In), and tin (Sn). Materials applied to the oxide semiconductor have been previously described, and thus further description thereof will be omitted.

Although not illustrated, a resistive contact member may be disposed on the semiconductor layer 130.

A first conductive material 140 is disposed over the semiconductor material 130, and a first photoresist 170 is disposed over the first conductive material 140 (see FIG. 5C).

A conductive material generally used to form a conductive wire may be utilized as the first conductive material 140, or a conductive material used to form the gate lines 212 and 312, and the gate electrodes 110a and 110b may be utilized as the first conductive material 140. The types of the first conductive material 140 have been previously described, and thus detailed description thereof will be omitted.

A conventional photoresist used for forming a metal pattern may be applied as the first photoresist 170.

Selective exposure is performed on the first photoresist 170 using a second pattern mask M2 and first etching is performed so that a photoresist pattern is formed (see FIG. 5D).

The first etching may include wet etching or dry etching. The etching method may be easily selected by those skilled in the art as necessary.

First and second semiconductor layers 130a and 130b may be formed by the first etching. The first semiconductor layer 130a may overlap at least a part of the first gate electrode 110a (e.g., in the horizontal direction as shown in FIG. 5D), and the second semiconductor layer 130b may overlap (e.g., in the horizontal direction as shown in FIG. 5D) at least a part of the second gate electrode 110b.

In the first etching, the first conductive materials 140a and 140b may not be removed from upper portions of the first and second semiconductor layers 130a and 130b. The semiconductor material and the first conductive material of a forming part of the data line 311 are patterned to form the data line 311. The data line 311 may have a structure in which a semiconductor material layer 130c and a first conductive material layer 140c are laminated. In addition to the data line 311, the semiconductor material and the first conductive material existing in a different wire part may also be patterned to be a wire. The semiconductor material 130 and the first conductive material 140 of the different wire part may be removed therefrom.

First photoresist patterns 171 and 172 remain on the upper portions of the first and second semiconductor layers 130a and 130b, and a first photoresist pattern 173 also remains on an upper portion of the data line 311.

Second etching is performed for the residual first photoresist patterns 171, 172, and 173 so that the first photoresist pattern 171 is all removed from the first semiconductor layer 130a, and the first photoresist pattern 172 is partly removed from the second semiconductor layer 130b, thereby forming two first photoresist patterns 174 and 175 that are separated from each other, and exposing the first conductive material 140b corresponding to a channel-forming part of the second semiconductor layer 130b (see FIG. 5E). The first photoresist pattern 173 on the data line 311 is secondarily etched to newly form a first photoresist pattern 176.

The first etching and the second etching may be continuously performed.

After the second etching, the first conductive material 140a is removed from the first semiconductor layer 130a, and the first conductive material 140b exposed in a position corresponding to the channel-forming part of the second semiconductor layer 130b is partly removed by a third etching in which etch selectivity is controlled. For example, the third etching removes the first conductive material 140a from the first semiconductor layer 130a and the first conductive material 140b from the channel-forming part of the second semiconductor layer 130b simultaneously and/or in a single fabrication processing step. Next, the remaining first photoresist patterns 174 and 175 are all removed. In this case, the first photoresist pattern 176 on the data line 311 is all removed so that the data line 311 is exposed (see FIG. 5F).

The first conductive material 140b on the second semiconductor layer 130b is separated from each other by the third etching, thereby forming a second source electrode 141 and a second drain electrode 142. Consequently, the second TFT 301 is formed. The structure of the second TFT 301 formed as described above is called a “back-channel-etch (BCE).”

Meanwhile, the source electrode and the drain electrode of the first TFT 201, which are made of the first conductive material 140, are not formed on the first semiconductor layer 130a as in the second TFT 301.

As an insulating layer, a passivation layer 150 is formed on the entire substrate including the driving unit and the display unit, namely an area including the data line 311, channel area of the first semiconductor layer 130a, the second source electrode 141, the second drain electrode 142, and the second semiconductor layer 130b (see FIG. 5G).

The passivation layer 150 may be made of an inorganic insulator such as silicon nitride (SiNx) or silicon oxide (SiOx), or may be made of an organic insulation material. Further, the passivation layer 150 may have a multilayer structure including inorganic and organic layers.

A second photoresist 180 is disposed over the passivation layer 150 (see FIG. 5H). The second photoresist 180 may be identical to or different from the first photoresist 170. A photoresist material suitable for the coating may be appropriately selected by those skilled in the art.

Selective exposure is performed on the second photoresist 180 by using a third pattern mask M3 and etching is performed to form first and second passivation layers 150a and 150b and second photoresist patterns 181 and 182 (see FIG. 5I). In this case, the second passivation layer 150b has a contact hole 155. Thus, in one example, the first passivation layer 150 and the contact hole 155 are formed simultaneously and/or in a single fabrication processing step. The channel area of the first TFT 201 is protected from the etching by the first passivation layer 150a that acts as an etch stopper.

Next, the second photoresist patterns 181 and 182 remaining on the first and second passivation layers 150a and 150b are removed therefrom (see FIG. 5J).

As described above, the first passivation layer 150a on the first semiconductor layer 130a may be a first insulating layer. The first passivation layer 150a may be disposed on an area corresponding to the channel area of the first semiconductor layer 130a.

Further, the second passivation layer 150b may be formed on the second source electrode 141 and the second drain electrode 142, and on the second semiconductor layer 130b between the second source electrode 141 and the second drain electrode 142. The second passivation layer 150b may be a second insulating layer.

The second passivation layer 150b may also be formed in a pixel area 302 where a pixel electrode 163 is formed.

A second conductive material is disposed over the entire substrate, e.g., the exposed first passivation layer 150a, the exposed second passivation layer 150b, and the exposed first semiconductor layer 130a, and the data line 311. Then, selective exposure is performed by using a fourth pattern mask M4 and etching is performed to form a first source electrode 161, a first drain electrode 162, and the pixel electrode 163 (see FIG. 5K). Thus, in one example, the first source and drain electrodes 161 and 162 and the pixel electrode 163 are formed simultaneously and/or in a single fabrication processing step.

In the example of FIG. 5K, the first source electrode 161 and the first drain electrode 162 are formed on a part of the first passivation layer 150a disposed on the first semiconductor layer 130a, and on the first semiconductor layer 130a separated from each other by the first passivation layer 150a, thereby forming the first TFT 201.

In this case, the pixel electrode 163 is formed on the second passivation layer 150b that is an insulating layer disposed in the pixel area, and the pixel electrode 163 and the second drain electrode 142 are connected to each other through the contact hole 155 in the second passivation layer 150b.

The first source electrode 161, the first drain electrode 162, and the pixel electrode 163 may be made of the second conductive material. The second conductive material may include a transparent conductive oxide (TCO) that is a transparent material.

Meanwhile, the first drain electrode 162 extends to an end portion of the data line 311 extending to the first TFT 201. As described above, the first drain electrode 162 and the data line 311 overlap each other so that the first drain electrode 162 may transmit signals easily to the data line 311.

In case where the pixel electrode 163 does not need to be transparent, the first source electrode 161, the first drain electrode 162, and the pixel electrode 163 may be formed by using an excellent conductor such as metals.

As such, according to an embodiment of the present invention, four pattern masks are used to fabricate a driving TFT and a pixel TFT, which are different from each other in configurations, on one substrate.

According to an embodiment of the present invention, the first TFT 201 has an etch stopper (ES) structure and the second TFT 301 has a back channel etch (BCE) structure.

The BCE type TFT has a relatively short channel in length, and thus a transistor area is not large and it is simple to fabricate the BCE type TFT. Therefore, the BCE type TFT is applied to the display unit according to an embodiment of the present invention. A high-resolution display device has particularly a small pixel area, and thus in the case of being applied with the BCE type TFT, a TFT area may be reduced in the pixel area.

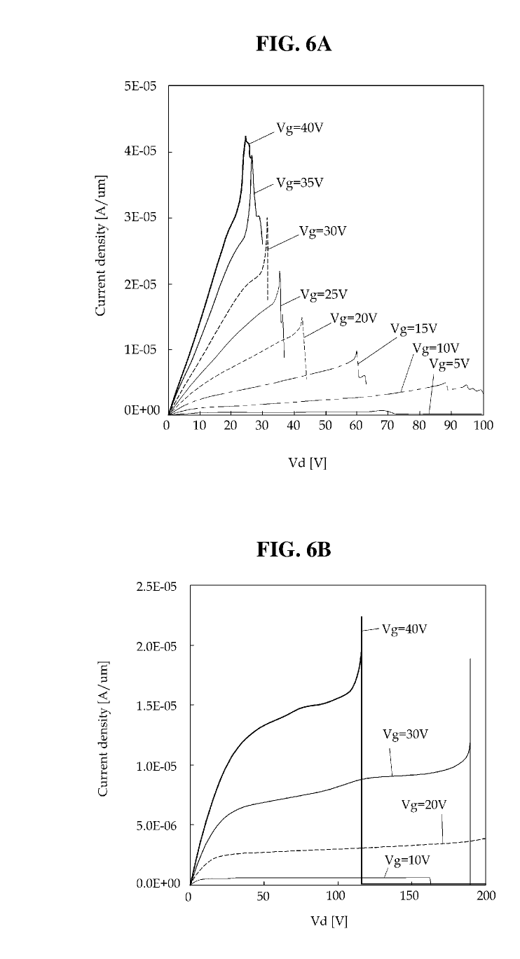

The ES type TFT has excellent driving properties. FIGS. 6 to 8 illustrate driving properties of a BCE type TFT having an IGZO-based oxide semiconductor and a ES type TFT having an IGZO-based oxide semiconductor.

For example, FIGS. 6A and 6B show drop in current density according to gate voltage. The drop in current density of the ES type TFT (see FIG. 6B) is more stable than the BCE type TFT (see FIG. 6A). In other words, in the case of the ES type TFT, the current density remains constant compared with that of the BCE type TFT until reaching a relatively high drain voltage (Vd) of 100V or more even though the gate voltage increases.

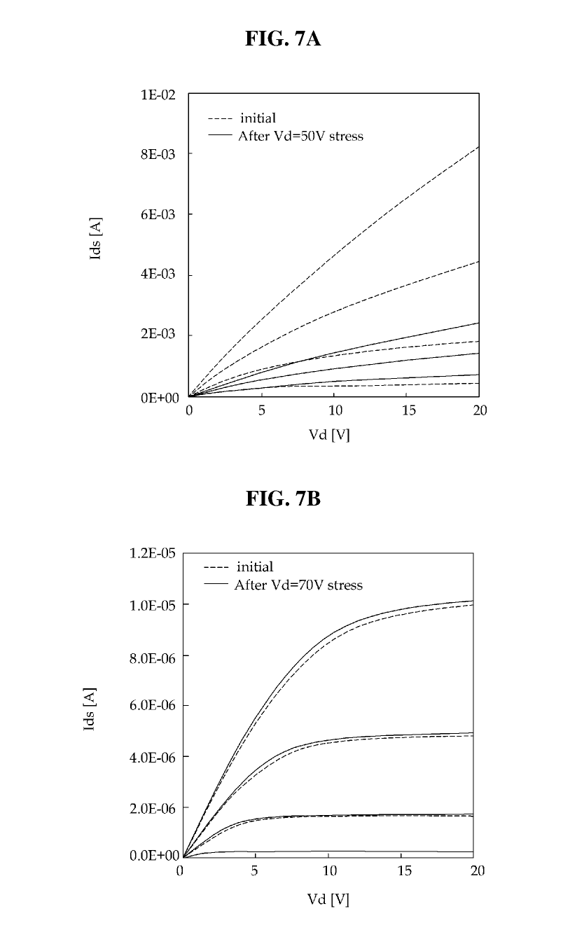

FIGS. 7A and 7B show a change of the current density before and after voltage stress. FIG. 7A shows a change of the current density before and after a voltage stress of 50V (Vd) is applied to the BCE type TFT, and FIG. 7B shows a change of the current density before and after a voltage stress of 70V (Vd) is applied to the ES type TFT. In the case of the ES type TFT (see FIG. 7B), the current density remains constant compared with that of the BCE type TFT (see FIG. 7A) after the voltage stress is applied.

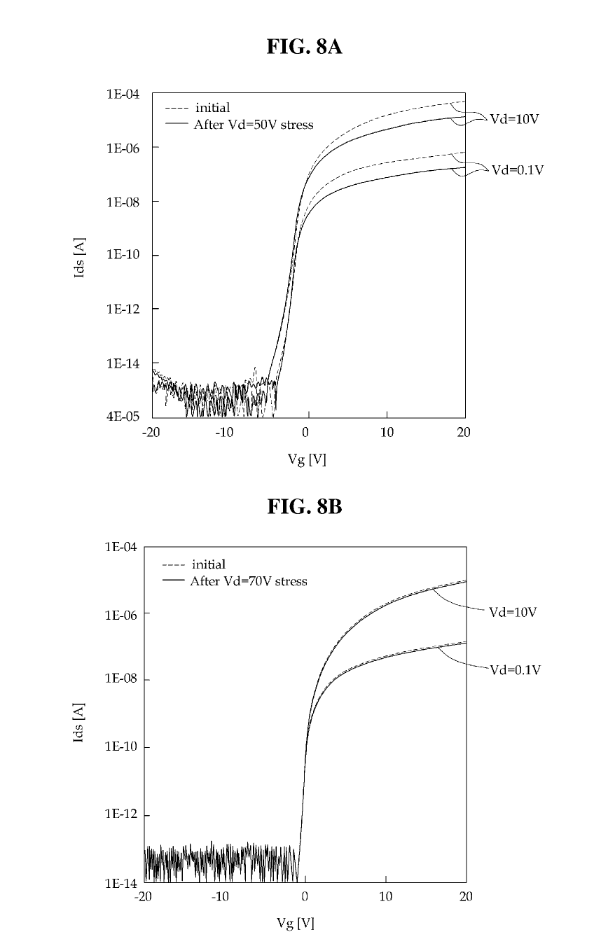

FIGS. 8A and 8B show a change of threshold voltage before and after voltage stress. FIG. 8A shows a change of the threshold voltage before and after a voltage stress of 50V (Vd) is applied to the BCE type TFT, and FIG. 8B shows a change of the threshold voltage before and after a voltage stress of 70V (Vd) is applied to the ES type TFT. In the case of the ES type TFT (see FIG. 8B), the threshold voltage remains constant compared with that of the BCE type TFT (see FIG. 8A).

According to an embodiment of the present invention, the ES type TFT having the above driving properties is used as the driving TFT.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims, and equivalents thereof.

What is claimed is:

1. A display device comprising:
a substrate;
a driving unit on the substrate, the driving unit comprising a first thin film transistor (TFT); and
a display unit on the substrate, the display unit being adjacent to the driving unit and comprising a second TFT,
wherein the first TFT comprises:
a first gate electrode on the substrate;
a first gate insulating layer on the first gate electrode;
a first semiconductor layer on the first gate insulating layer, overlapping at least a part of the first gate electrode;
a first insulating layer on at least a part of the first semiconductor layer; and
a first source electrode and a first drain electrode partly on the first semiconductor layer and partly on the first insulating layer, the first source and drain electrodes being spaced apart from each other, and
the second TFT comprises:
a second gate electrode on the substrate;
a second gate insulating layer on the second gate electrode;
a second semiconductor layer on the second gate insulating layer, overlapping at least a part of the second gate electrode;
a second source electrode and a second drain electrode on the second semiconductor layer, the second source and drain electrodes being spaced apart from each other; and
a second insulating layer on the second source electrode and the second drain electrode.

2. The display substrate of claim 1, further comprising a pixel electrode on the second insulating layer, the pixel electrode being connected to the second drain electrode through a contact hole in the second insulating layer.

3. The display substrate of claim 2, wherein the pixel electrode is made of the same material as the first source electrode and the first drain electrode.

4. The display substrate of claim 3, wherein the pixel electrode, the first source electrode, and the first drain electrode comprise at least one selected from the group consisting of metals and transparent conducting oxides (TCOs).

5. The display substrate of claim 1, wherein the first semiconductor layer and the second semiconductor layer are an oxide semiconductor layer.

6. The display substrate of claim 5, wherein the oxide semiconductor layer comprises at least one selected from the group consisting of zinc (Zn), gallium (Ga), indium (In), and tin (Sn).

7. The display substrate of claim 5, wherein the oxide semiconductor layer comprises indium (In), gallium (Ga), zinc (Zn), and oxygen (O).

8. The display substrate of claim 1, further comprising an etch stopper on the first semiconductor layer.

9. The display substrate of claim 1, wherein the first insulating layer is made of the same material as the second insulating layer.

10. The display substrate of claim 1, wherein the driving unit comprises at least one of a data driver and a gate driver.

11. A method of manufacturing a display substrate, the method comprising:
forming a first gate electrode and a second gate electrode on a substrate;
forming a gate insulating layer on the first gate electrode and the second gate electrode;
forming a first semiconductor layer and a second semiconductor layer respectively overlapping at least a part of the first gate electrode and a part of the second gate electrode on the gate insulating layer;
forming a first insulating layer on at least a part of the first semiconductor layer;
forming a first source electrode and a first drain electrode spaced apart from each other on the first semiconductor layer and the first insulating layer;
forming a second source electrode and a second drain electrode spaced apart from each other on the second semiconductor layer; and
forming a second insulating layer on the second source electrode and the second drain electrode, having a contact hole configured to expose a part of the second drain electrode.

12. The method of claim 11, further comprising forming a pixel electrode connected to the second drain electrode through the contact hole in the second insulating layer.

13. The method of claim 12, wherein the forming of the pixel electrode is performed simultaneously with the forming of the first source electrode and the first drain electrode.

14. The method of claim 13, wherein the forming of the pixel electrode and the forming of the first source electrode and the first drain electrode comprises:
coating the first semiconductor layer, the first insulating layer, and the second insulating layer with a second conductive material; and
selectively etching the second conductive material.

15. The method of claim 11, wherein the forming of the first and second semiconductor layers and the forming of the second source electrode and the second drain electrode are performed by the same mask.

16. The method of claim 15, wherein the forming of the first and second semiconductor layers and the forming of the second source electrode and the second drain electrode comprises:
sequentially coating the gate insulating layer with a semiconductor material and a first conductive material; and
selectively etching the semiconductor material and the first conductive material.

17. The method of claim 16, wherein the semiconductor material comprises an oxide semiconductor material.

18. The method of claim 11, wherein the forming of the first insulating layer is performed simultaneously with the forming of the second insulating layer.
